(19) United States
(12) Patent Application Publication
(10) Pub. No.: US 2024/0319422 A1
(43) Pub. Date: Sep. 26, 2024

(54) Optical Film and Display System Including Same

(71) Applicant: 3M INNOVATIVE PROPERTIES COMPANY, St. Paul, MN (US)

(72) Inventors: Yu Hsin Lu, Dacun Township (TW); Chiu-Hsing Lin, Taoyuan City (TW); Ryan T. Fabick, Shoreview, MN (US); Masaki Yamamuro, Tokyo (JP)

(21) Appl. No.: 18/579,434

(22) PCT Filed: Jul. 18, 2022
(86) PCT No.: PCT/IB2022/056590

§ 371 Date: Jan. 15, 2024

Related U.S. Application Data
(60) Provisional application No. 63/227,787, filed on Jul. 30, 2021.

(51) Int. Cl. G02B 5/28; H01L 25/075

(52) U.S. Cl. CPC G02B 5/287; H01L 25/0753

(57) ABSTRACT

An optical film includes a plurality of polymeric layers, such that a transmittance of the polymeric layers versus wavelength includes: a left band edge separating a wavelength range where the polymeric layers has a transmittance of greater than about 60% from a wavelength range where the polymeric layers has a reflectance of greater than about 80%; and a mid-wavelength corresponding to a transmittance of about 50% along the left band edge. A display system includes a light converting film having green and red emission spectra including respective green and red emission peaks with respective green and red full width at half maxima (FWHMs); and includes the optical film disposed on the light converting film. For each of the FWHMs, the mid-wavelength is less than or equal to a shortest wavelength of the FWHM or greater than the shortest wavelength by no more than about 30% of the FWHM.

### SUMMARY

According to some aspects of the present description, a display system is provided. The display system includes a light converting film including one or more light converting materials having green and red emission spectra including respective green and red emission peaks at respective green and red peak wavelengths with respective green and red full width at half maxima (FWHMs). Each of the FWHMs extends from a lower first wavelength to a higher second wavelength. The display system includes a first optical film disposed on the light converting film and including a plurality of first polymeric layers numbering at least 10 in total where each of the first polymeric layers having an average thickness of less than about 500 nm, such that for a substantially normally incident light and for at least a first polarization state, an optical transmittance of the plurality of first polymeric layers versus wavelength includes: a left band edge separating a shorter wavelength range where the plurality of first polymeric layers has an optical transmittance of greater than about 60% from a middle wavelength range where the plurality of first polymeric layers has an optical reflectance of greater than about 80%, and a right band edge separating the middle wavelength range from a longer wavelength range where the plurality of first polymeric layers has an optical transmittance of greater than about 60%; and a mid-wavelength corresponding to an optical transmittance of about 50% along the left band edge. For each of the FWHMs, the mid-wavelength is less than or equal to the lower first wavelength of the FWHM or greater than the lower first wavelength by no more than about 30% of the FWHM.

According to some aspects of the present description, an optical film including a plurality of polymeric layers numbering at least 10 in total is provided. Each of the polymeric layers has an average thickness of less than about 500 nm, such that for a substantially normally incident light and for at least a first polarization state, an optical transmittance of the plurality of first polymeric layers versus wavelength includes: a left band edge separating a shorter wavelength range where the plurality of first polymeric layers has an optical transmittance of greater than about 60% from a middle wavelength range where the plurality of first polymeric layers has an optical reflectance of greater than about 80%, and a right band edge separating the middle wavelength range from a longer wavelength range where the plurality of first polymeric layers has an optical transmittance of greater than about 60%; and first and second mid-wavelengths corresponding to optical transmittances of about 50% along the respective left and right band edges. Across at least 80% of the optical film, the first mid-wavelength has an average value LBE50 between about 480 nm and about 530 nm with a maximum value that is greater than LBE50 by no more than about 4% and a minimum value that is less than LBE50 by no more than about 4%, and the second mid-wavelength has an average value RBE50 between about 820 nm and about 870 nm with a maximum value that is greater than RBE50 by no more than about 1% and a minimum value that is less than RBE50 by no more than about 5%. Best left and right linear fits to the respective left and right band edges at least across wavelength ranges where the optical transmittance changes from about 70% to about 20% have respective left and right slopes, where a ratio of a magnitude of the left slope to a magnitude of the right slope is greater than about 1.2.

These and other aspects will be apparent from the following detailed description. In no event, however, should this brief summary be construed to limit the claimable subject matter.

### BRIEF DESCRIPTION OF THE DRAWINGS

FIG. 1 is a schematic exploded cross-sectional view of a display system, according to some embodiments.

FIG. 2A is a schematic cross-sectional view of a multilayer optical film, according to some embodiments.

FIG. 2B is a schematic cross-sectional view of a mirror film, according to some embodiments.

FIG. 2C is a schematic cross-sectional view of a reflective polarizer, according to some embodiments.

FIGS. 3A-3B are plots of optical transmittances of a plurality of polymeric layers versus wavelength, according to some embodiments.

FIGS. 4A-4C are plots of optical transmittances of a plurality of polymeric layers and intensity of light emitted from a light conversion film versus wavelength, according to some embodiments.

FIG. 5 is a plot of band edges of optical transmittances of a plurality of polymeric layers versus wavelength, according to some embodiments.

FIG. 6 is a schematic plot of band edge wavelengths versus position, according to some embodiments.

### DETAILED DESCRIPTION

In the following description, reference is made to the accompanying drawings that form a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

Display systems can include blue light emitting diodes (LEDs) and a color converting film (e.g., a quantum dot film or a phosphor film) disposed to receive light from the blue LEDS and convert portions of the blue light to green and red light while transmitting a portion of the blue light. An optical film having a blue reflection band can be placed between the color converting film and the blue LEDs to recycle light from the LEDs in order to improve efficiency. However, it has been found that overlap between the green emission spectra and a left band edge of the blue reflection band can create undesired color mura. According to some embodiments of the present description, it has been found that the position of the left band edge of the blue reflection band of the optical film relative to the smallest wavelength of a full width at half maximum of the green emission spectra can be selected to reduce the color mura. Moreover, it has been found that the optical film can be made such that the blue reflection band has band edges that are substantially uniform over the optical film so that the left band edge of the blue reflection band has a substantially constant position relative to the smallest wavelength of the full width at half maximum of the green emission spectra so that color mura is reduced for substantially any portion of the optical film used in a display.

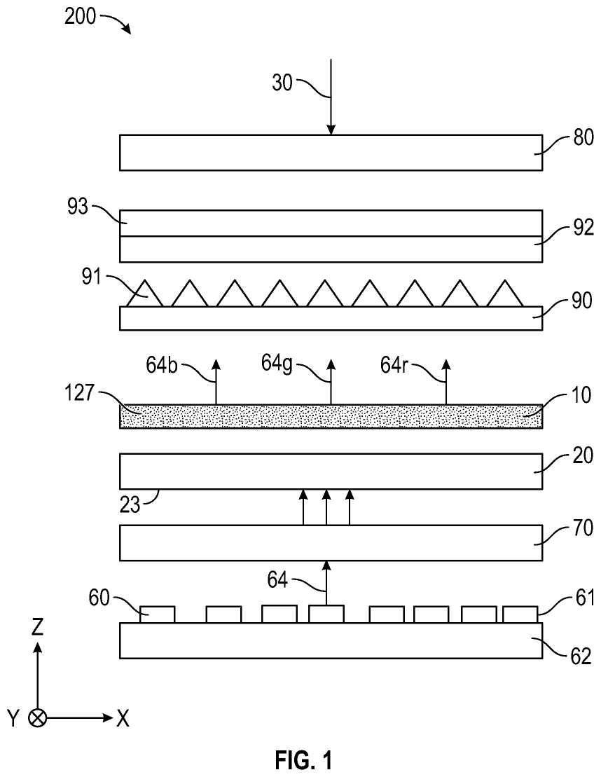

FIG. 1 is a schematic exploded cross-sectional view of a display system 200 including a light converting film 10 and a first optical film 20 disposed on the light converting film 10, according to some embodiments. The display system can include a plurality of discrete spaced apart light emitting sources 60, where the first optical film 20 is disposed between the light converting film 10 and the light emitting sources 60, such that emission surfaces 61 of the light emitting sources 60 face a major surface 23 of the first optical film 20. The plurality of discrete spaced apart light emitting sources 60 can be configured to emit light 64 having wavelengths of less than about 490, or 480, or 470, or 460, or 455, or 450 nm. The emitted light can be primarily in a range of about 410 nm to about 490 nm (e.g., greater than 50% or 60% or 70% of the emitted light intensity can be in this wavelength range), for example. The light emitting sources 60 can be disposed on a common substrate 62. The light converting film 10 may be configured to convert portions of the light 64 into green and red lights 64g and 64r and to transmit a portion of the light 64 as a blue light 64b.

The display system 200 can further include optical elements conventionally included in a liquid crystal display, for example. The display system 200 can include an optical diffuser film 70 disposed between the first optical film 20 and the light emitting sources 60 and configured to receive and scatter the emitted light 64. The diffuser film 70 may be included for defect hiding, for example. The display system 200 can include a reflective polarizer 80, where the light converting film 10 is disposed between the reflective polarizer 80 and the first optical film 20. The reflective polarizer 80 can be included for polarization recycling, for example. The display system 200 can include a first prismatic film 90 disposed between the reflective polarizer 80 and the light converting film 10. The first prismatic film 90 can include a plurality of first prisms 91 extending along a first longitudinal direction (e.g., y-direction). The display system 200 can include a second prismatic film 92 disposed between the reflective polarizer 80 and the first prismatic film 90. The second prismatic film 92 can include a plurality of second prisms 93 extending along a second longitudinal direction (e.g., x-direction) different than the first longitudinal direction. The second longitudinal direction can be substantially orthogonal to the first longitudinal direction. The prism film(s) can be included to enhance on-axis brightness, for example. Suitable prism films include Brightness Enhancement Film (BEF) available from 3M Company, St. Paul, MN.

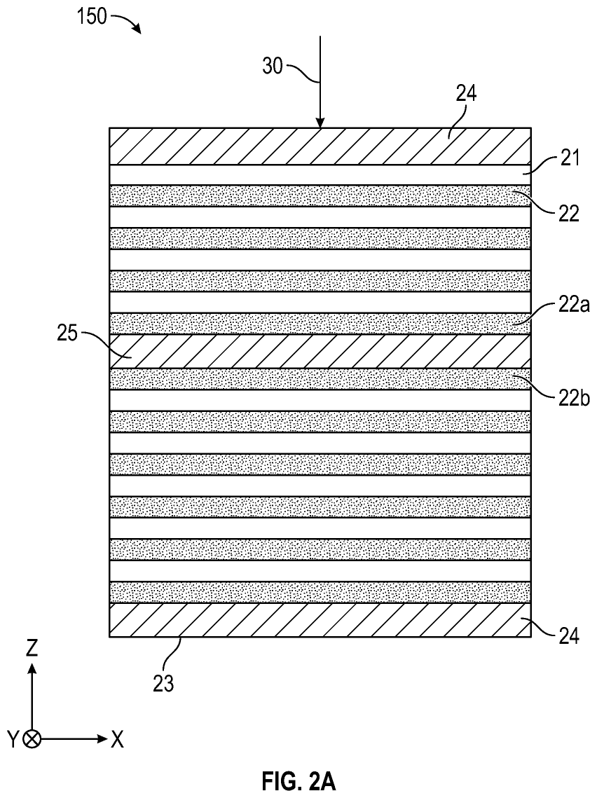

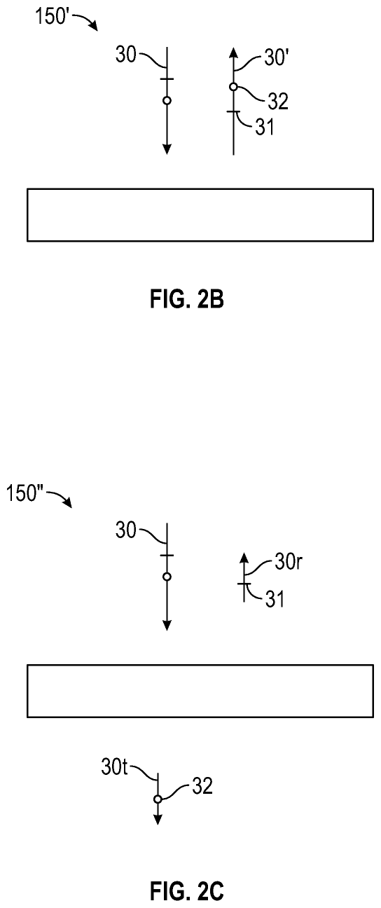

FIG. 2A is a schematic cross-sectional view of a multilayer optical film 150, according to some embodiments. The multilayer optical film 150 may be a mirror film as schematically illustrated in FIG. 2B for optical film 150′ which may correspond to optical film 150, or may be a reflective polarizer as schematically illustrated in FIG. 2C for optical film 150″ which may correspond to optical film 150. In FIG. 2B, the optical film 150′ substantially reflects the substantially normally incident light 30 for each of orthogonal first and second polarization states 31 and 32 as reflected light 30′. In FIG. 2C, the optical film 150″ substantially reflects the substantially normally incident light 30 having the first polarization state 31 as reflected light 30r and substantially transmits the substantially normally incident light 30 having the second polarization state 32 as transmitted light 30t. The first optical film 20 and/or the reflective polarizer 80 may be as schematically illustrated for multilayer optical film 150. The optical film 20 may be as schematically illustrated for optical film 150′, for example, and the reflective polarizer 80 may be as schematically illustrated for optical film 150″.

As is known in the art, multilayer optical films including alternating polymeric layers can be used to provide desired reflection and transmission in desired wavelength ranges by suitable selection of layer thicknesses and refractive index differences. Multilayer optical films and methods of making multilayer optical films are described in U.S. Pat. No. 5,882,774 (Jonza et al.); 6,179,948 (Merrill et al.); 6,783,349 (Neavin et al.); 6,967,778 (Wheatley et al.); and 9,162,406 (Neavin et al.), for example.

In some embodiments, the first optical film 20 includes a plurality of first polymeric layers 21, 22 numbering at least 10, 20, 50, 75, 100, 150, 200, 250, 300, 350, or 400 in total. The plurality of first polymeric layers 21, 22 may number up to 1500 or 1000 in total. For example, the plurality of first polymeric layers 21, 22 may number from 10 to 1500 or from 20 to 1000 in total. In some embodiments, each of the first polymeric layers has an average thickness of less than about 500, 400, 350, 300, 250, or 200 nm. The average thickness may be at least about 20 nm or at least about nm. For example, each of the first polymeric layers has an average thickness in a range of about nm to about 500 nm or about 40 nm to about 400 nm. The optical film 20 can include other layers such as protective boundary layers (intermediate layers) between packets of the first polymeric layers 21, 22 and/or skin layers as outer layers of the optical film. In some embodiments, the first optical film 20 includes at least one skin layer 24 having an average thickness of greater than about 500. In some embodiments, the first optical film 20 further includes at least one intermediate layer 25 disposed between two of the first polymeric layers (22a, 22b) and having an average thickness of greater than about 500 nm. The at least one skin layer 24 and/or the at least intermediate layer 25 can have an average thickness greater than about 750, 1000, 1500, or 2000 nm, for example. The average thickness can be up to about 30 micrometer or up to about 20 micrometers, for example.

In some embodiments, the reflective polarizer 80 includes a plurality of second polymeric layers 21, 22 numbering at least 10 in total. The total number of second polymeric layers can be in any of the ranges described for the first polymeric layers. In some embodiments, each of the second polymeric layers has an average thickness of less than about 500 nm, such that for a substantially normally incident (e.g., within about 30, 20, 10, or 5 degrees of normally incident) light 30, the plurality of second polymeric layers reflect more than about 60% of the incident light having the first polarization state 31 and transmit more than about 60% of the incident light having an orthogonal second polarization state 32. Each of the second polymeric layers can have an average thickness in a range described for the first polymeric layers. The reflective polarizer 80 may include skin and/or intermediate layer(s) as described for the first optical film 20. In some embodiments, the plurality of second polymeric layers reflect more than about 70%, 80%, or 90% of the incident light having the first polarization state 31. In some embodiments, the plurality of second polymeric layers transmit more than about 70%, 80%, or 90% of the incident light having the second polarization state 32. The reflection and/or transmission may be in any of the above ranges for at least one wavelength in a visible wavelength range or the average reflection and/or transmission over a visible wavelength range may be in any of these ranges. The visible wavelength range may be 400 nm to 700 nm or 420 nm to 680, for example.

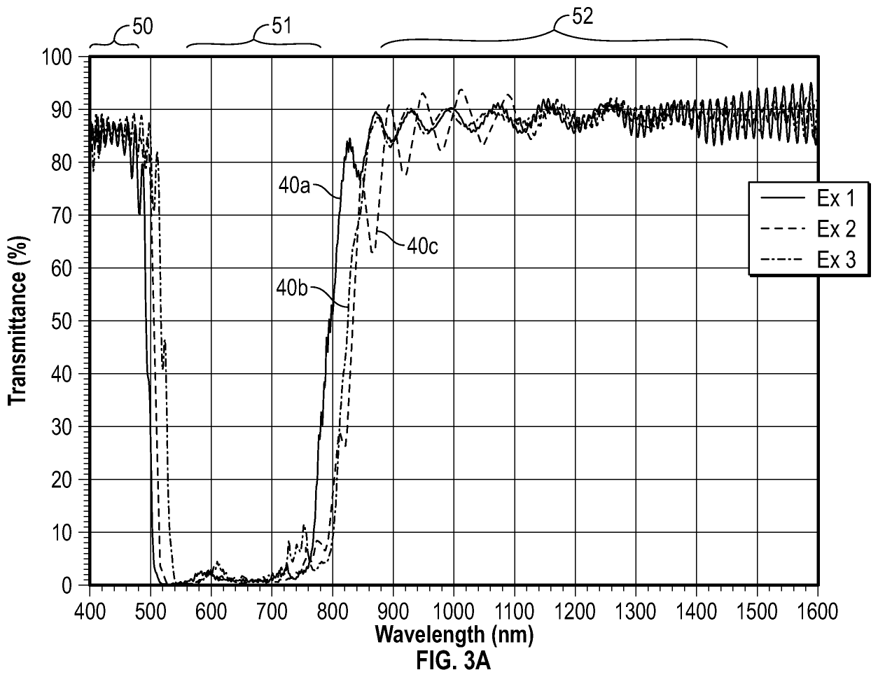

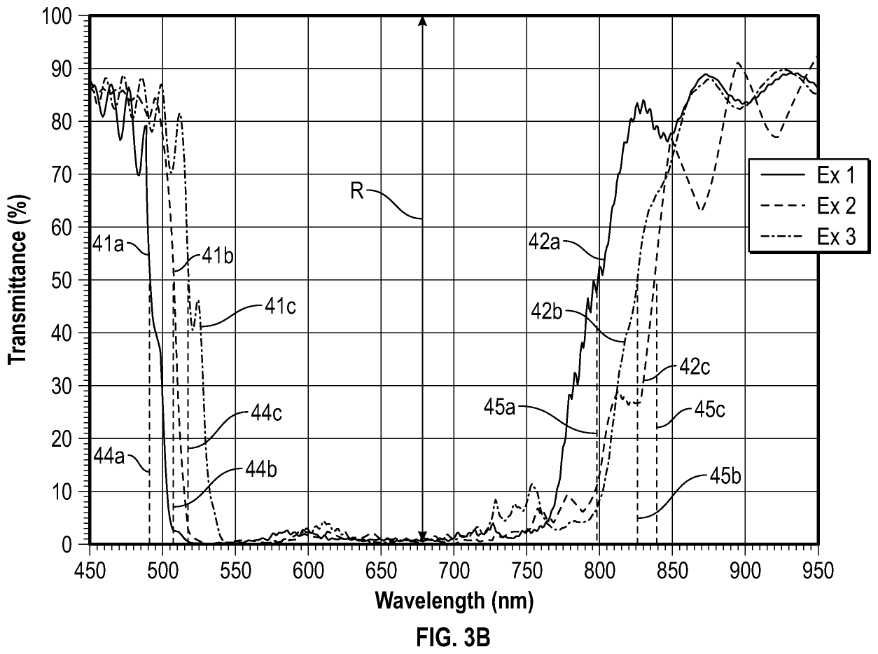

FIGS. 3A-3B are plots of optical transmittances 40a-40c of a plurality of polymeric layers 21, 22 versus wavelength, according to some embodiments. The optical transmittances 40a-40c are for respective optical films Ex1, Ex2, and Ex3. The optical transmittances 40a-40c have respective left band edges 41a-41c and corresponding first mid-wavelengths 44a-44c where the optical transmittance is about 50% and respective right band edges 42a-42c and corresponding second mid-wavelengths 45a-45c where the optical transmittance is about 50%. Average optical transmittances in various wavelength ranges are reported in the table below.

| Wavelength range (nm) | Ex1 | Ex2 | Ex3 |
|---|---|---|---|
| 420-480 | 84.3 | 85.8 | 85.9 |
| 490-520 | 18.4 | 49.3 | 74.0 |
| 530-680 | 1.08 | 0.96 | 1.53 |
| 900-1400 | 88.5 | 88.3 | 88.6 |

The optical films of FIGS. 3A-3B were made by co-extrusion and biaxial orientation as generally described in U.S. Pat. Appl. Pub. No. 2001/0013668 (Neavin et al.), with exceptions as follows. The films included alternating first (21) and second (22) optical layers (layers having a thickness less than about 500 nm so that the layers can reflect and transmit light primarily by optical interference) having a layer thickness profile giving the optical transmittance of FIGS. 3A-3B. The first optical layers were comprised of polyethylene terephthalate (PET) homopolymer. The second optical polymer layers were a copolymer of poly(methyl methacrlatemethacrylate) or coPMMA available from Plaskolite, Columbus, OH, USA under the tradename OPTIX. The polymer used for the skin layers were comprised of the same material used in the first optical layers. The materials were fed from separate extruders to a multilayer coextrusion feedblock, in which they were assembled. The skin layers were added to the construction in a manifold specific to that purpose, resulting in a final construction having 429 layers. The multilayer melt was then cast through a film die onto a chill roll, in the conventional manner for polyester films, upon which it was quenched. The cast web was then stretched in a commercial scale biaxial tenter at temperatures and draw profiles similar to those described in U.S. Pat. Appl. Pub. No. 2001/0013668 (Neavin et al.). The resulting films were measured for physical thickness by a capacitance gauge. The average thickness was approximately 54.9 μm as measured using an Ono-Sokki DG-925 Micrometer. It has been found that the resulting optical films can have left and right band edge wavelengths that are substantially uniform over substantially a total area of the optical film. The optical films Ex1, Ex2, and Ex3 are different film samples made using the same process and can represent different portions of a same film made using the same process. Other suitable polymers that can be used for the various layers of the optical films are described in U.S. Pat. No. 5,882,774 (Jonza et al.); 6,179,948 (Merrill et al.); 6,783,349 (Neavin et al.); 6,967,778 (Wheatley et al.); and 9,162,406 (Neavin et al.), for example.

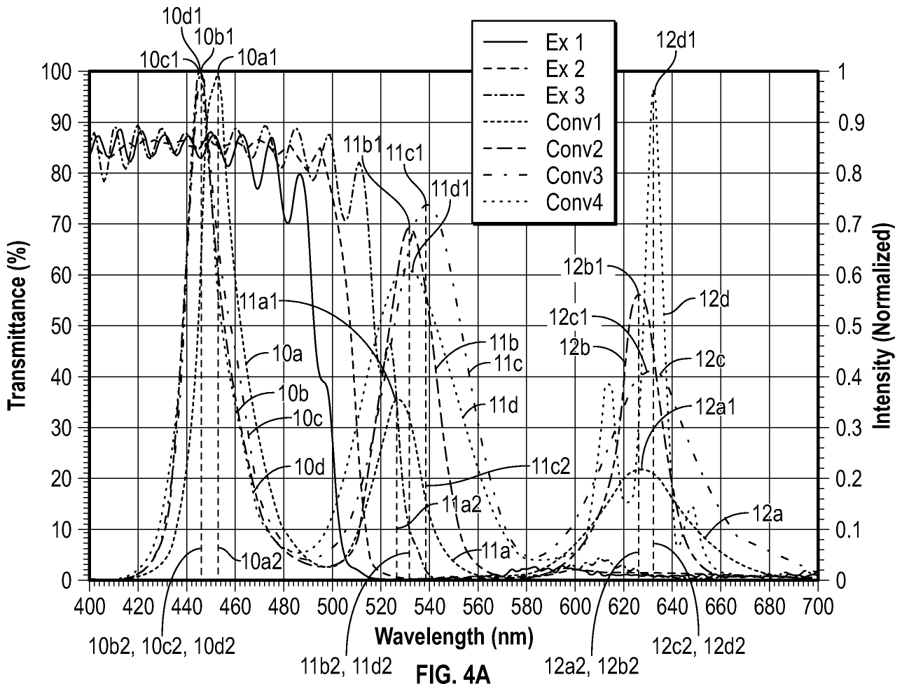

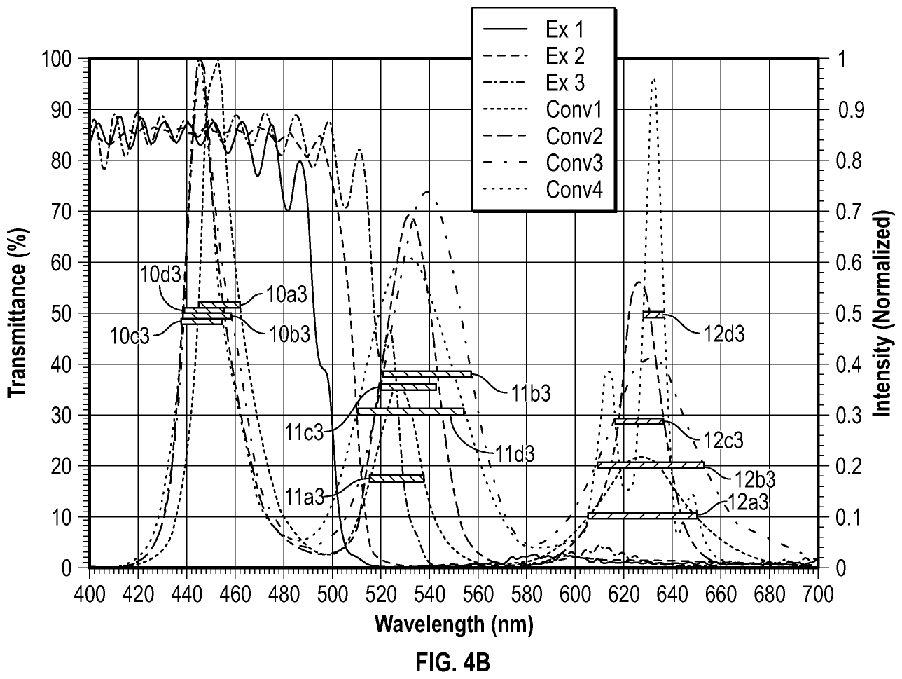

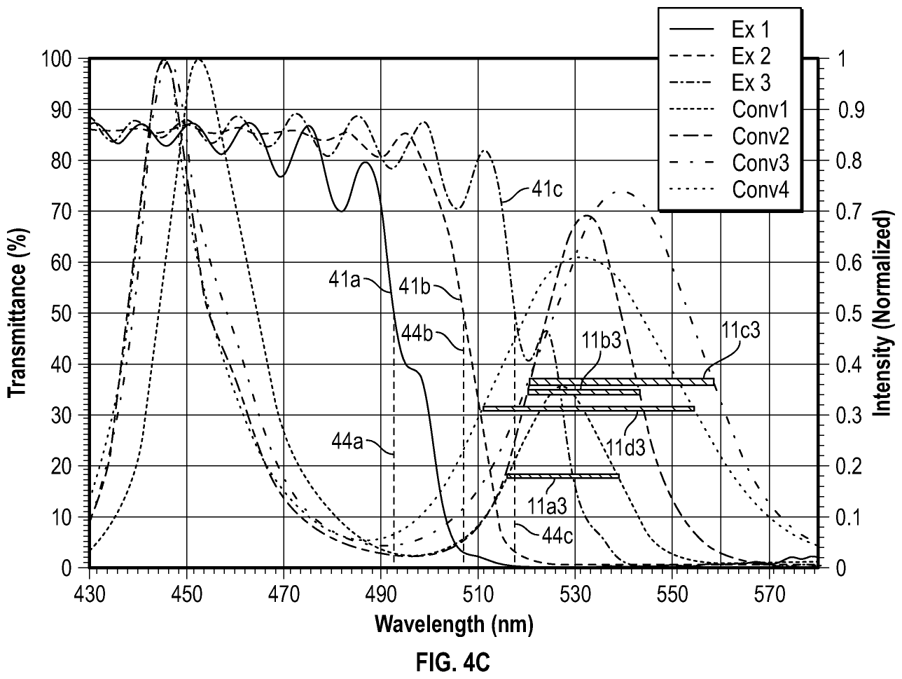

FIGS. 4A-4C are plots of optical transmittances of FIGS. 3A-3B superimposed on a plot of intensity of light emitted from a light conversion film 10 versus wavelength when illuminated with light from a blue light emitting diode (LED), according to some embodiments. The intensity is shown for four light conversion films labeled Conv1-Conv4. Conv1 and Conv2 are quantum dot films available from Showa Denko K. K. (Tokyo, Japan), Conv3 is a quantum dot film available from Inno QD (Korea), and Conv4 is a phosphor film available from Dexerials Corporation (Tokyo, Japan).

In some embodiments, a display system 200 includes a light converting film 10 including one or more light converting materials 127 having green (11a-11d) and red (12a-12d) emission spectra including respective green (11a1-11d1) and red (12a1-12d1) emission peaks at respective green (11a2-11d2) and red (12a2-12d2) peak wavelengths with respective green (11a3-11d3) and red (12a3-12d3) full width at half maxima (FWHMs). The FWHMs are schematically represented by the widths of horizontal bars in FIGS. 4B-4C. Each of the FWHMs extend from a lower first wavelength to a higher second wavelength. In some embodiments, a first optical film 20 can be disposed on the light converting film 10 and includes a plurality of first polymeric layers 21, 22 such that for a substantially normally incident light 30 and for at least a first polarization state (31 and/or 32), an optical transmittance (40a-40c) of the plurality of first polymeric layers versus wavelength includes: a left band edge (41a-41c) separating a shorter wavelength range 50 (e.g., about 400 or 420 nm to about 480 nm) where the plurality of first polymeric layers has an optical transmittance of greater than about 60% from a middle wavelength range 51 (e.g., about 530 nm to about 680 or 760 nm) where the plurality of first polymeric layers has an optical reflectance (e.g., the optical reflectance R schematically illustrated in FIG. 3B) of greater than about 80%, and a right band edge 42a-42c separating the middle wavelength range 51 from a longer wavelength range 52 (e.g., about 880 nm to about 1450 nm or about 900 to about 1400 nm) where the plurality of first polymeric layers has an optical transmittance of greater than about 60%; and a mid-wavelength 44a-44c corresponding to an optical transmittance of about 50% along the left band edge. In some embodiments, for each of the FWHMs, the mid-wavelength 44a-44c is less than or equal to the lower first wavelength (e.g., for 11b3, 11c3) of the FWHMs or greater than the lower first wavelength (e.g., for 11a3, 11d3) by no more than about 30% of the FWHM. Here, 30% of the FWHM means 30% of the total width (difference between the higher second wavelength and the lower first wavelength) of the FWHM. In some embodiments, for each of the FWHMs, the mid-wavelength 44a-44c is no greater than the first wavelength plus 0.3, or 0.2, or 0.1 times a difference between the second wavelength and the first wavelength. In some embodiments, the mid-wavelength 44a-44c is greater than (e.g., by at least 20 nm, or at least 30 nm) a peak emission wavelength (e.g., 10b1-10d1) of the light emitting sources 60 or greater than (e.g., by at least 20 nm, or at least 30 nm) a blue peak transmission wavelength (e.g., 10a1-10d1) of the received light 64 transmitted by the light converting film 10.

In some embodiments, the plurality of first polymeric layers has an optical transmittance (e.g., the optical transmittance for at least one wavelength in the shorter wavelength range 50, or the optical transmittance for each wavelength in the shorter wavelength range 50, or for an average of the optical transmittance in the shorter wavelength range 50) of greater than about 60%, 65%, 70%, 75%, or 80% in the shorter wavelength range 50. In some embodiments, the plurality of first polymeric layers has an optical reflectance (e.g., the optical reflectance for at least one wavelength in the middle wavelength range 51, or the optical reflectance for each wavelength in the middle wavelength range 51, or for an average of the optical reflectance in the middle wavelength range 51) of greater than about 80%, 85%, 90%, 95%, 96%, or 97%, 98%, or 98.5% in the middle wavelength range 51. In some embodiments, the plurality of first polymeric layers has an optical transmittance (e.g., the optical transmittance for at least one wavelength in the longer wavelength range 52, or the optical transmittance for each wavelength in the longer wavelength range 52, or for an average of the optical transmittance in the longer wavelength range 52) of greater than about 60%, 65%, 70%, 75%, 80%, or 85% in the longer wavelength range 52. In some embodiments, the optical transmittance and/or optical reflectance is in any of these ranges for each of orthogonal first (31) and second (32) polarization states.

In some embodiments, the light emitting sources 60 are configured to emit light primarily in the shorter wavelength range 50. In some embodiments, the light converting film 10 is configured to receive the emitted light 64 from the light sources 60 and convert at least: a first portion (corresponding to the green emission peak 11a1-11d1) of the received emitted light to a green light 64g having a green wavelength disposed within the green FWHM of the green emission spectra of the light converting film 10; and a second portion (corresponding to the red emission peak 12a1-12d1) of the received emitted light to a red light 64r having a red wavelength disposed within the red FWHM of the red emission spectra of the light converting film 10. In some embodiments, the light converting film 10 is configured to transmit a third portion (corresponding to the blue transmission peak 10b1-10d1 or the transmitted portion of the peak 10a1) of the received emitted light 64 as a blue light 64b. In some embodiments, the light converting film 10 (e.g., light converting films Conv2-Conv4) substantially transmits a third portion of the received emitted light 64 as a blue light without substantially shifting a blue peak wavelength of the received emitted light 63. In some embodiments, the light converting film 10 (e.g., light converting film Conv1) substantially transmits a third portion of the received emitted light 64 as a blue light having a longer blue peak wavelength than that of the received emitted light 63.

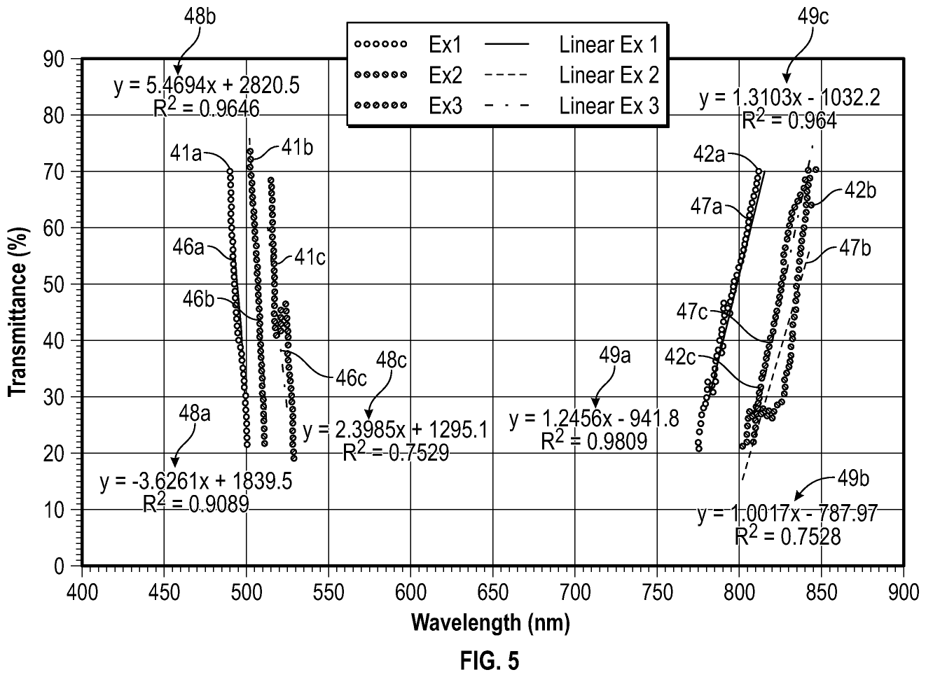

FIG. 5 is a plot of band edges of optical transmittances of a plurality of polymeric layers versus wavelength, according to some embodiments. Left band edges 41a-41c and respective right band edges 42a-42c are shown for the optical transmittances of the respective optical films Ex1-Ex3 and best linear fits to the band edges are also shown. A high band edge slope (e.g., greater than about 2%/nm, or greater than about 3%/nm, or greater than about 3.5%/nm) may be desired for the left band edges so that there is a sharp transition in optical transmittance between blue and green emission wavelengths while the right band edge may have a lower slope (e.g., less than about 1.4%/nm, or less than about 1.3%/nm, or less than about 1.25%/nm). The left band edge can be sharpened by using additional optical layers providing reflection at wavelengths near the left band edge. Such band edge sharpening techniques are known in the art and are described in U.S. Pat. No. 6,967,778 (Wheatley et al.), for example. In some embodiments, best left (46a-46c) and right (47a-47c) linear fits to the respective left and right band edges at least across wavelength ranges where the optical transmittance changes from about 70% to about 20% have respective left (48a-48c) and right (49a-49c) slopes, where a ratio of a magnitude of the left slope to a magnitude of the right slope is greater than about 1.2, 1.5, 1.8, 2, 3, 4, or 5, for example. The ratio can be up to about 10, 8, or 6, for example. In some embodiments, the ratio of the magnitude of the left slope to the magnitude of the right slope is in a range of about 1.5 to about 6, for example. The best linear fits can be linear least squares fits as is known in the art. Such fits minimize the sum of squares of residuals where a residual is the difference between data and the fitted line. The least squares analysis allows the r-squared value (R²), sometimes referred to as the coefficient of determination, to be determined. The r-squared value for the best left (46a-46c) and/or right (47a-47c) linear fits may be greater than about 0.7, 0.75, 0.8, 0.85, or 0.9, for example.

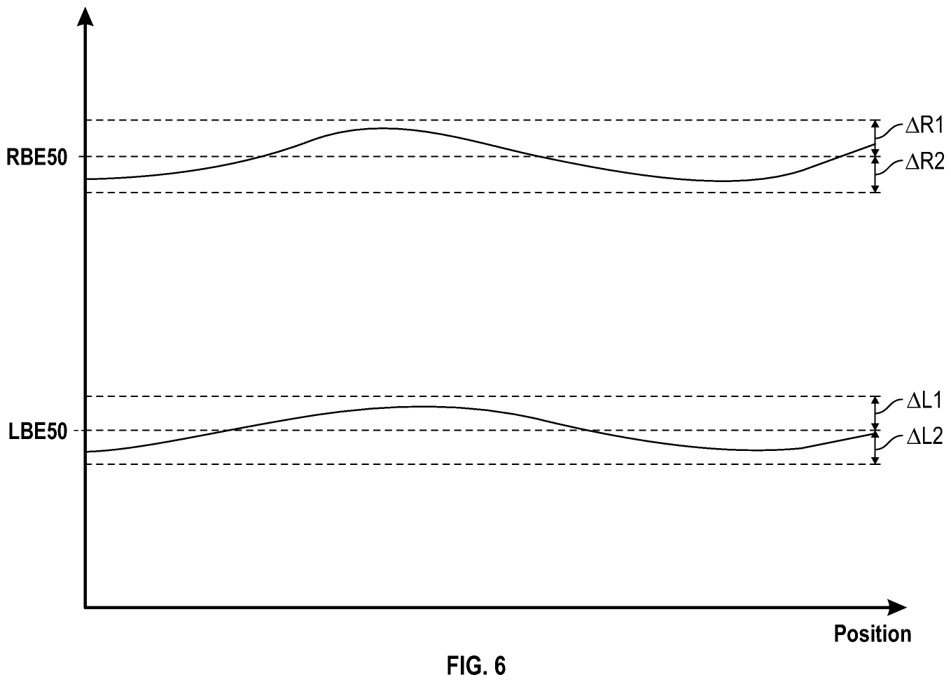

FIG. 6 is a schematic plot of band edge wavelengths versus position, according to some embodiments. The position can be the cross-web location, for example. In some embodiments, the band edge wavelengths are substantially uniform across at least 80% of the optical film 20. Across at least a specified percentage of an optical film means across at least the specified percentage by area of the optical film, unless indicated differently. In FIG. 6, the optical film has a left band edge mid-wavelength having an average value LBE50, a maximum value greater than LBE50 by no more than AL1, a minimum value less than LBE50 by no more than AL2, and the optical film has a right band edge mid-wavelength having an average value RBE50, a maximum value greater than RBE50 by no more than AR1, a minimum value less than RBE50 by no more than AR2. In some embodiments, LBE50 is between about 460 nm and about 540 nm, or between about 480 nm and about 530 nm, or between about 490 nm and about 520 nm. In some such embodiments, or in other embodiments, RBE50 is between about 770 nm and about 880 nm, or between about 800 nm and about 875 nm, or between about 820 nm and about 870 nm. In some embodiments, each of AL1 and AL2 is no more than about 5% or no more than about 4% of LBE50. In some embodiments, each of AR1 and AR2 is no more than about 5% or no more than about 4% of RBE50.

In some embodiments, across at least 80%, 85%, 90%, 95%, 98%, or 99% of the (first) optical film 20, the (first) mid-wavelength 44a-44c (see, e.g., FIG. 3B) has an average value LBE50 between about 480 nm and about 530 nm with a maximum value that is greater than LBE50 by no more than about 4% and a minimum value that is less than LBE50 by no more than about 4%. In some embodiments, the maximum value is greater than LBE50 by no more than about 3.5% or no more than about 3%. In some embodiments, the minimum value is less than LBE50 by no more than about 3.5% or no more than about 3%. In some embodiments, across at least 80%, 85%, 90%, 95%, 98%, or 99% of the (first) optical film 20, the second mid-wavelength 44a-44c (see, e.g., FIG. 3B) has an average value RBE50 between about 820 nm and about 870 nm with a maximum value that is greater than RBE50 by no more than about 1% and a minimum value that is less than RBE50 by no more than about 5%. In some embodiments, the maximum value is greater than RBE50 by no more than about 0.9%, 0.8%, 0.7%, or 0.6%. In some embodiments, the minimum value is less than RBE50 by no more than about 4.5%, 4%, 3.8%, or 3.6%.

Terms such as “about” will be understood in the context in which they are used and described in the present description by one of ordinary skill in the art. If the use of “about” as applied to quantities expressing feature sizes, amounts, and physical properties is not otherwise clear to one of ordinary skill in the art in the context in which it is used and described in the present description, “about” will be understood to mean within 10 percent of the specified value. A quantity given as about a specified value can be precisely the specified value. For example, if it is not otherwise clear to one of ordinary skill in the art in the context in which it is used and described in the present description, a quantity having a value of about 1, means that the quantity has a value between 0.9 and 1.1, and that the value could be 1.

Terms such as “substantially” will be understood in the context in which they are used and described in the present description by one of ordinary skill in the art. If the use of “substantially” with reference to a property or characteristic is not otherwise clear to one of ordinary skill in the art in the context in which it is used and described in the present description and when it would be clear to one of ordinary skill in the art what is meant by an opposite of that property or characteristic, the term “substantially” will be understood to mean that the property or characteristic is exhibited to a greater extent than the opposite of that property or characteristic is exhibited.

All references, patents, and patent applications referenced in the foregoing are hereby incorporated herein by reference in their entirety in a consistent manner. In the event of inconsistencies or contradictions between portions of the incorporated references and this application, the information in the preceding description shall control.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations, or variations, or combinations of the specific embodiments discussed herein. Therefore, it is intended that this disclosure be limited only by the claims and the equivalents thereof.

1. A display system comprising:
a light converting film comprising one or more light converting materials comprising green and red emission spectra comprising respective green and red emission peaks at respective green and red peak wavelengths with respective green and red full width at half maxima (FWHMs), each of the FWHMs extending from a lower first wavelength to a higher second wavelength; and
a first optical film disposed on the light converting film and comprising a plurality of first polymeric layers numbering at least 10 in total, each of the first polymeric layers having an average thickness of less than about 500 nm, such that for a substantially normally incident light and for at least a first polarization state, an optical transmittance of the plurality of first polymeric layers versus wavelength comprises:
a left band edge separating a shorter wavelength range where the plurality of first polymeric layers has an optical transmittance of greater than about 60% from a middle wavelength range where the plurality of first polymeric layers has an optical reflectance of greater than about 80%, and a right band edge separating the middle wavelength range from a longer wavelength range where the plurality of first polymeric layers has an optical transmittance of greater than about 60%; and
a mid-wavelength corresponding to an optical transmittance of about 50% along the left band edge, wherein for each of the FWHMs, the mid-wavelength is less than or equal to the lower first wavelength of the FWHM or greater than the lower first wavelength by no more than about 30% of the FWHM.

2. The display system of claim 1 further comprising a plurality of discrete spaced apart light emitting sources configured to emit light having wavelengths of less than about 490 nm, the first optical film disposed between the light converting film and the light emitting sources, such that emission surfaces of the light emitting sources face a major surface of the first optical film.

3. The display system of claim 2, wherein the light converting film is configured to receive the emitted light from the light sources and convert at least:
a first portion of the received emitted light to a green light having a green wavelength disposed within the green FWHM of the green emission spectra of the light converting film; and
a second portion of the received emitted light to a red light having a red wavelength disposed within the red FWHM of the red emission spectra of the light converting film.

4. The display system of claim 3, wherein the light converting film is configured to transmit a third portion of the received emitted light as a blue light.

5. The display system of claim 2 further comprising an optical diffuser film disposed between the first optical film and the light emitting sources and configured to receive and scatter the emitted light.

6. The display system of claim 2, wherein the light emitting sources are disposed on a common substrate.

7. The display system of claim 1, further comprising a reflective polarizer, the light converting film disposed between the reflective polarizer and the first optical film, the reflective polarizer comprising a plurality of second polymeric layers numbering at least 10 in total, each of the first polymeric layers having an average thickness of less than about 500 nm, such that for a substantially normally incident light, the plurality of second polymeric layers reflect more than about 60% of the incident light having the first polarization state and transmit more than about 60% of the incident light having an orthogonal second polarization state.

8. The display system of claim 7 further comprising a first prismatic film disposed between the reflective polarizer and the light converting film and comprising a plurality of first prisms extending along a first longitudinal direction.

9. The display system of claim 8 further comprising a second prismatic film disposed between the reflective polarizer and the first prismatic film and comprising a plurality of second prisms extending along a second longitudinal direction different than the first longitudinal direction.

10. The display system of claim 1, wherein the first optical film further comprises at least one skin layer having an average thickness of greater than about 500 nm.

11. The display system of claim 1, wherein the first optical film further comprises at least one intermediate layer disposed between two of the first polymeric layers and having an average thickness of greater than about 500 nm.

12. The display system of claim 1, wherein across at least 80% of the first optical film, the mid-wavelength has an average value LBE50 between about 480 nm and about 530 nm with a maximum value that is greater than LBE50 by no more than about 4% and a minimum value that is less than LBE50 by no more than about 4%.

13. An optical film comprising a plurality of polymeric layers numbering at least 10 in total, each of the polymeric layers having an average thickness of less than about 500 nm, such that for a substantially normally incident light and for at least a first polarization state, an optical transmittance of the plurality of first polymeric layers versus wavelength comprises:
a left band edge separating a shorter wavelength range where the plurality of first polymeric layers has an optical transmittance of greater than about 60% from a middle wavelength range where the plurality of first polymeric layers has an optical reflectance of greater than about 80%, and a right band edge separating the middle wavelength range from a longer wavelength range where the plurality of first polymeric layers has an optical transmittance of greater than about 60%; and
first and second mid-wavelengths corresponding to optical transmittances of about 50% along the respective left and right band edges, wherein across at least 80% of the optical film, the first mid-wavelength has an average value LBE50 between about 480 nm and about 530 nm with a maximum value that is greater than LBE50 by no more than about 4% and a minimum value that is less than LBE50 by no more than about 4%, and the second mid-wavelength has an average value RBE50 between about 820 nm and about 870 nm with a maximum value that is greater than RBE50 by no more than about 1% and a minimum value that is less than RBE50 by no more than about 5%,
wherein, best left and right linear fits to the respective left and right band edges at least across wavelength ranges where the optical transmittance changes from about 70% to about 20% have respective left and right slopes, wherein a ratio of a magnitude of the left slope to a magnitude of the right slope is greater than about 1.2.

14. The optical film of claim 13, wherein the ratio of the magnitude of the left slope to the magnitude of the right slope is in a range of about 1.5 to about 6.

15. A display system comprising:
a light converting film comprising one or more light converting materials comprising green and red emission spectra comprising respective green and red emission peaks at respective green and red peak wavelengths with respective green and red full width at half maxima (FWHMs), each of the FWHMs extending from a lower first wavelength to a longer second wavelength; and
the optical film of claim 13 disposed on the light converting film, wherein for each of the FWHMs, LBE50 is less than or equal to the lower first wavelength of the FWHM or greater than the lower first wavelength by no more than about 30% of the FWHM.
